(19) United States
(12) Patent Application Publication
(10) Pub. No.: US 2013/0048581 A1
(43) Pub. Date: Feb. 28, 2013

(54) SLIDABLE SUPPORTING MECHANISM

(71) Applicant: SZU-WEI KUO, Tu-Cheng (TW)

(72) Inventor: SZU-WEI KUO, Tu-Cheng (TW)

(73) Assignee: HON HAI PRECISION INDUSTRY CO., LTD., Tu-Cheng (TW)

(21) Appl. No.: 13/278,142

(22) Filed: Oct. 20, 2011

(30) Foreign Application Priority Data
Aug. 29, 2011 (TW) 100130850

(51) Int. Cl. H05K 7/18

(52) U.S. Cl. 211/26

(57) ABSTRACT

A slidable supporting mechanism includes two slide rails and a supporting device. The supporting device is connected in a longitudinal slidable manner between the slide rails, and includes a bottom plate for supporting a server and evening out the weight of the server, two side plates extending up from opposite sides of the bottom plate, and two slide arms respectively extending outwards from the tops of the side plates. The slide arms are slidably supported on tops of the slide rails so that the supporting mechanism has a high bearing capacity.

### BACKGROUND

1. Technical Field

The present disclosure relates to a slidable supporting mechanism.

2. Description of Related Art

Conventionally, two slide rails are mounted to the opposite sides of a rack, to allow a server to be mounted between the slide rails. However, a server is generally very heavy, if the weight bearing ability of the slide rails are low, the slide rails are likely to be bent during installation of the server.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawing, all the views are schematic, and like reference numerals designate corresponding parts throughout the several views.

FIG. 1 is an assembled, isometric view of an exemplary embodiment of a slidable supporting mechanism, including two slide rails and a supporting device.

FIG. 2 is an enlarged view of the supporting device of FIG. 1.

FIG. 3 is an exploded, isometric view of a server and the supporting device of FIG. 1, but shows the server is cutaway.

FIG. 4 is an assembled, isometric view of FIG. 3.

FIG. 5 is a cross-sectional view taken along the line V-V of FIG. 4.

FIGS. 6 and 7 are assembled, isometric views of additional embodiments of a slidable supporting mechanism.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

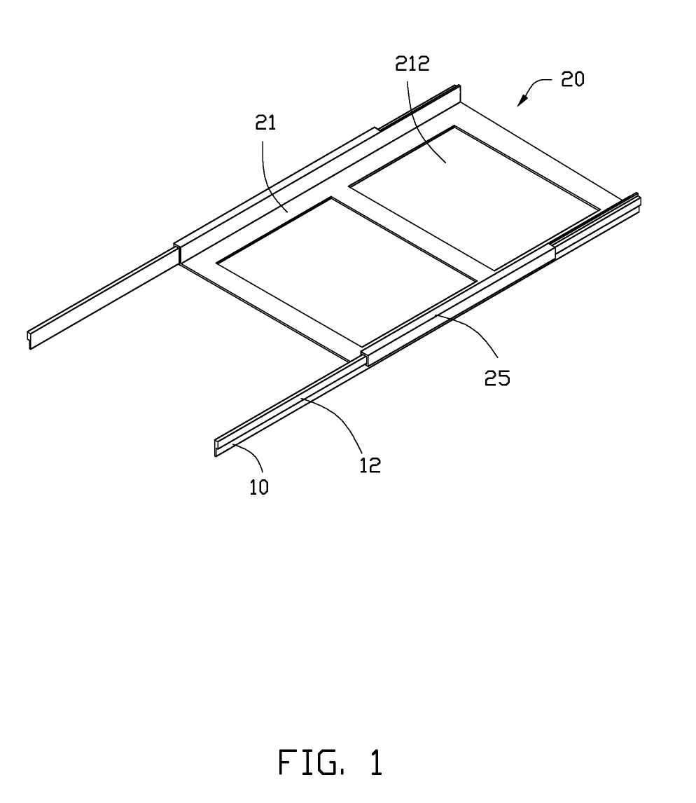

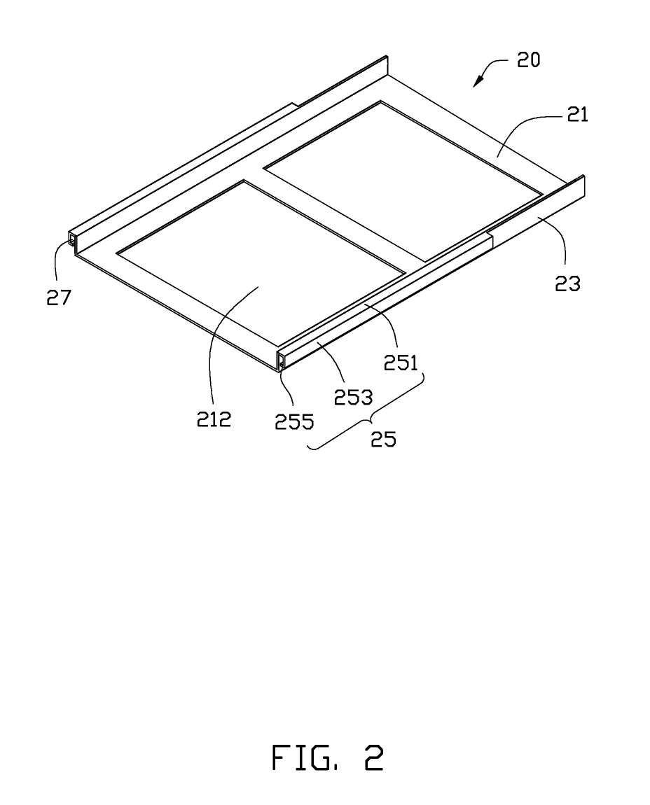

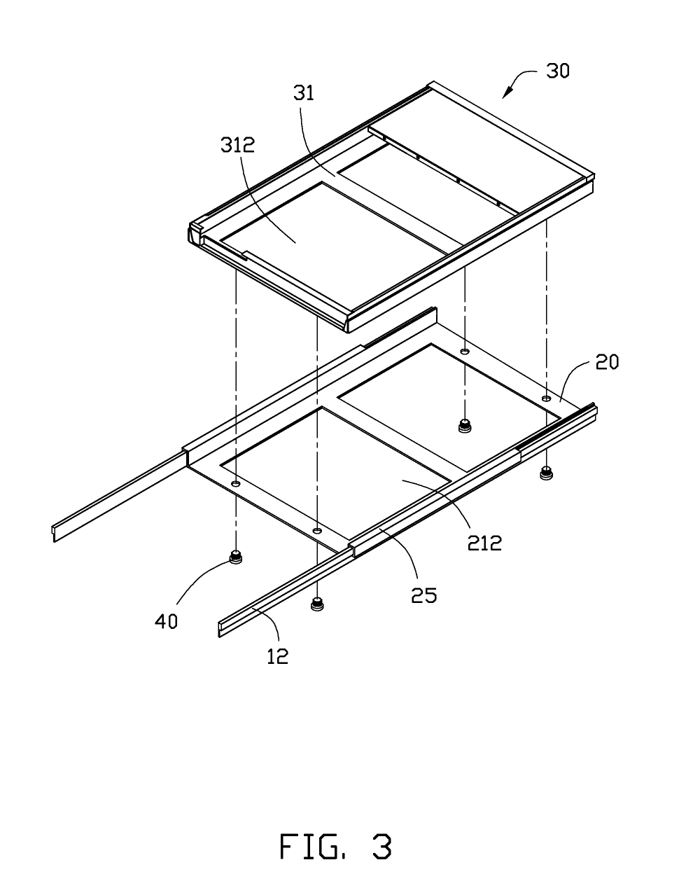

Referring to FIGS. 1 to 3, an exemplary embodiment of a slidable supporting mechanism is provided to support a server 30. The supporting mechanism includes two slide rails 10 and a supporting device 20.

The server 30 includes a bottom wall 31. Two spaced protruding portions 312 extend down from the bottom wall 31.

Each slide rail 10 includes a flange 12 longitudinally extending from the upper portion of the outer side of the slide rail 10.

The supporting device 20 is stamped out of a sheet metal, and includes a bottom plate 21, two side plates 23 perpendicularly extending upwards from opposite sides of the bottom plate 21, and two slide arms 25 respectively extending outwards from the tops of the side plates 23. The front ends of the bottom plate 21 and the side plates 23 are exposed out of the front ends of the slide arms 25. Two spaced openings 212 are defined in the bottom plate 21, corresponding to the protruding portions 312 of the server 30. Each slide arm 25 includes a top wall 251 perpendicularly connected to the top of the corresponding side plate 23. A sidewall 253 perpendicularly extends downwards from a side of the top wall 251, away from the corresponding side plate 23. An extension wall 255 extends from the bottom of the sidewall 253 towards and spaced from the corresponding side plate 23. A slide slot 27 is bounded by the top wall 251, the sidewall 253, and the extension wall 255.

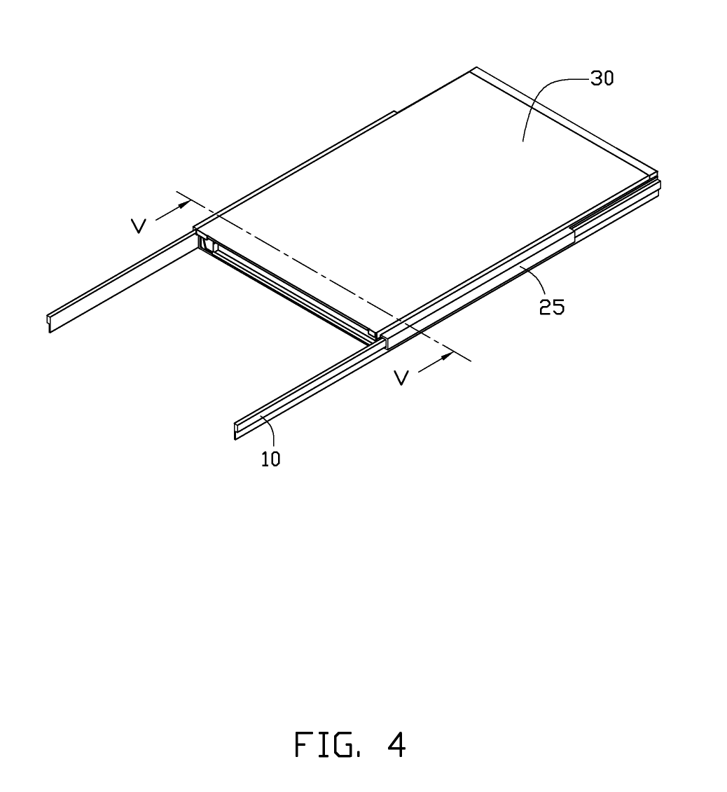

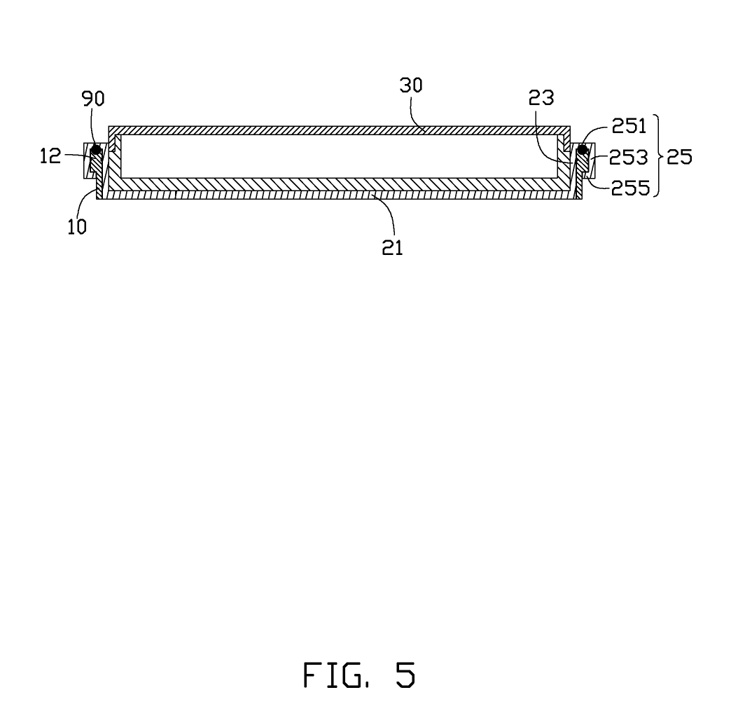

Referring to FIGS. 4 and 5, to assemble the supporting mechanism, the flanges 12 are respectively extended through the slide slots 27, to allow the slide arms 25 to be slidably connected to the upper portions of the slide rails 10, respectively. The slide rails 10 is mounted to opposite sides of a rack (not shown), with the front end of the supporting device 20 aligning with an opening of the rack. When the supporting device 20 is pulled forward, the front ends of the bottom plate 21 and the side plates 23 are capable of extending out of the rack. A plurality of ball bearings 90 can be mounted to the inner surfaces of the top walls 251 and contacts the tops of the slide rails 10, or can be mounted to the tops of the slide rails 10 and contacts the inner surfaces of the top walls 251, for facilitating the sliding movement of the supporting device 20 relative to the slide rails 10.

To install the server 30 in the rack, the front ends of the bottom plate 21 and the side plates 23 are pulled out of the rack. The server 30 is placed on the bottom plate 21, with the protruding portions 312 received in the openings 212, respectively. The supporting device 20 is pushed into the rack, thereby the server 30 is installed in the rack. In other embodiments, a plurality of screws 40 is provided to extend through the bottom plate 21 and engage in the bottom wall 31, to fasten the server 30 to the supporting device 20.

In the installation process, because the supporting device 20 is slidably connected between the slide rails 10, the bottom plate 21 can support the server 30 and even out the weight of the server 30, so that the supporting device 20 is not likely to deform. The slide arms 25 are slidably supported on the tops of the corresponding slide rails 10, so that the slide rails 10 and the side plates 23 are not likely to deform, the supporting mechanism has a high bearing capacity. The openings 212 receive the protruding portions 312, which can make the server 30 be firmly mounted on the bottom plate 21, and allow heat produced by the server 30 to be dissipated through the openings 212.

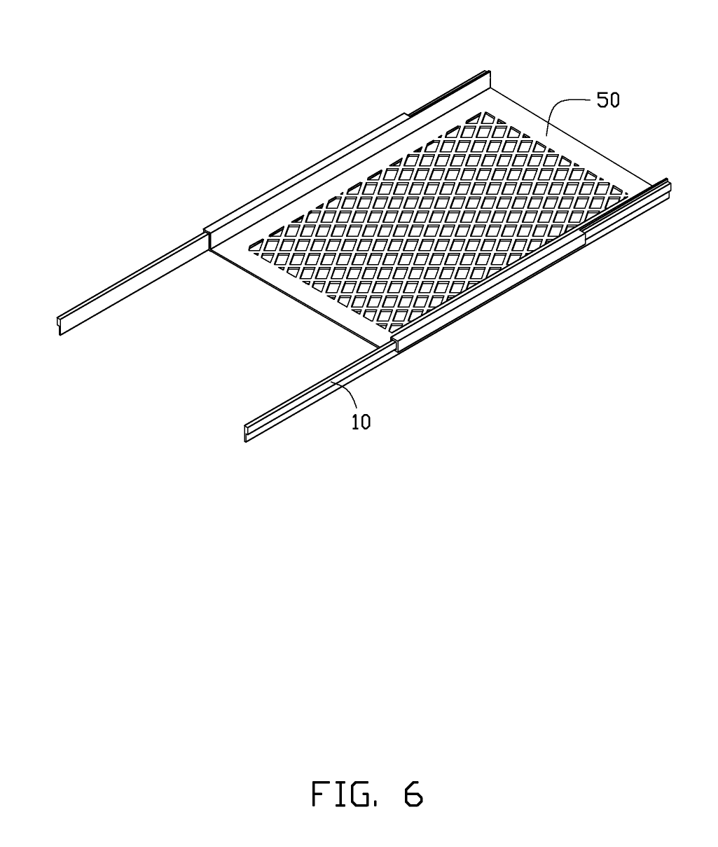

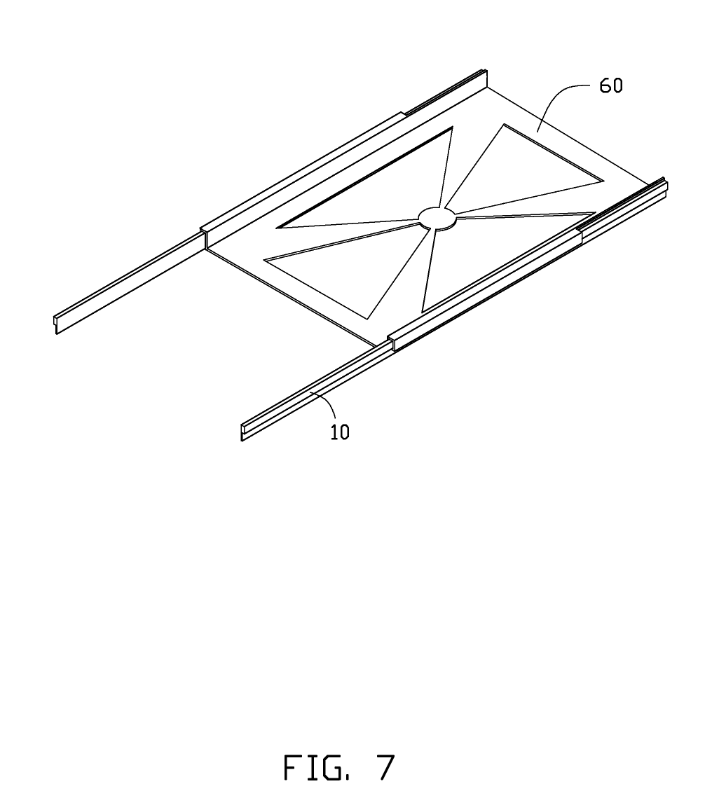

Referring to FIGS. 6 and 7, in other embodiments, according to different shapes of protruding portions of different servers, the supporting device 20 may be replaced with supporting devices 50 or 60 which has different openings.

Even though numerous characteristics and advantages of the embodiments have been set forth in the foregoing description, together with details of the structure and the functions of the embodiments, the disclosure is illustrative only, and changes may be made in details, especially in matters of shape, size, and arrangement of parts within the principles of the embodiments to the full extent indicated by the broad general meaning of the terms in which the appended claims are expressed.

What is claimed is:

1. A slidable supporting mechanism, comprising:
two slide rails; and
a supporting device connected in a longitudinally slidable manner between the slide rails, the supporting device comprising a bottom plate for supporting a server, two side plates extending up from opposite sides of the bottom plate, and two slide arms respectively extending outwards from tops of the side plates, wherein the slide arms are slidably supported on the slide rails.

2. The slidable supporting mechanism of claim 1, wherein a front end of the bottom plate is exposed out of front ends of the slide arms.

3. The slidable supporting mechanism of claim 1, wherein a flange longitudinally extends from an upper portion of an outer side of each slide rail, each slide arm comprises a top wall connected in a substantially perpendicular manner to a top of a corresponding one of the side plates, a sidewall extending in a substantially perpendicular manner down from a side of the top wall away from the corresponding side plate, and an extension wall extending from a bottom of the sidewall towards and spaced from the corresponding side plate, a slide slot is bounded by the top wall, the sidewall, and the extension wall, the flanges of the slide rails are slidably received in the slide slots, respectively.

4. The slidable supporting mechanism of claim 3, wherein a plurality of ball bearings is mounted to an inner surface of each top wall, and contacts a corresponding one of the slide rails.

5. The slidable supporting mechanism of claim 3, wherein a plurality of ball bearings is mounted to the top of each slide rail, and contacts the an inner surface of a corresponding one of the top walls.

6. The slidable supporting mechanism of claim 1, wherein the supporting device is stamped out of a sheet metal.

7. The slidable supporting mechanism of claim 1, wherein at least one opening is defined in the bottom plate of the supporting device, for receiving at least one corresponding protruding portion formed on a bottom of the server.

8. A slidable supporting mechanism, comprising:
two slide rails; and
a supporting device connected in a longitudinally slide manner between the slide rails, the supporting device comprising a bottom plate for supporting a server, two side plates extending up from opposite sides of the bottom plate, and two slide arms respectively extending outwards from tops of the side plates, wherein the slide arms are slidably placed around tops of the slide rails.

9. The slidable supporting mechanism of claim 8, wherein a front end of the bottom plate is exposed out of front ends of the slide arms.

10. The slidable supporting mechanism of claim 8, wherein a flange longitudinally extends from an upper portion of each slide rail, each slide arm defines a longitudinally extending slide slot, the flanges of the slide rails are slidably received in the slide slots, respectively.

11. The slidable supporting mechanism of claim 10, wherein a plurality of ball bearings is mounted between each slide arm and a corresponding one of the slide rails.

12. The slidable supporting mechanism of claim 8, wherein the supporting device is stamped out of a sheet metal.

13. The slidable supporting mechanism of claim 8, wherein at least one opening is defined in the bottom plate of the supporting device, for receiving at least one corresponding protruding portion formed on a bottom of the server.
